(19) United States
(12) Patent Application Publication
(10) Pub. No.: US 2004/0113218 A1
(43) Pub. Date: Jun. 17, 2004

(54) Photosensitive assembly with a transparent layer and method for manufacturing the same

(76) Inventors: Jachson Hsieh, Hsinchu Hsien (TW); Jichen Wu, Hsinchu Hsien (TW)

Correspondence Address: PRO-TECHTOR INTERNATIONAL, 20775 Norada Court, Saratoga, CA, 95070-3018, US

(21) Appl. No.: 10/321,913

(22) Filed: Dec. 16, 2002

(51) Int. Cl. B32B 3/00; H01L 31/00

(52) U.S. Cl. 257/432; 257/433; 257/434; 257/436

(57) ABSTRACT

A photosensitive assembly with a transparent layer and a method for manufacturing the same. The method includes the steps of: providing a wafer having a plurality of photosensitive chips, each photosensitive chip having a photosensitive region and a plurality of bonding pads formed at a periphery of the photosensitive region; providing a plurality of transparent layers on the photosensitive regions of the photosensitive chips, respectively; and cutting the wafer into photosensitive assemblies using a cutter. Thus, each photosensitive chip may receive optical signals passing through the transparent layer.

### BACKGROUND OF THE INVENTION

1. Field of the Invention

The invention relates to a photosensitive assembly with a transparent layer and a method for manufacturing the same, and more particularly to a method for providing a transparent layer on a wafer and then cutting the wafer into a plurality of photosensitive assemblies.

2. Description of the Related Art

A general sensor is used for sensing signals, which may be optical or audio signals. The sensor of the invention is used for receiving image signals or optical signals. After receiving image signals, the image sensor converts the image signals into electrical signals, which are then transmitted to a printed circuit board via a substrate.

Referring to FIG. 1, a conventional method for packaging an image sensor includes the steps of:

providing a substrate 10 having an upper surface formed with first contact points 18 and a lower surface formed with second contact points 24;

providing a frame layer 12 on the substrate 10 to form a cavity 11;

providing a photosensitive chip 14 on the substrate 10 and within the cavity 11, a plurality of bonding pads 20 being formed on the photosensitive chip 14;

providing a plurality of wires 16 for electrically connecting the bonding pads 20 of the photosensitive chip 14 to the first contact points 18 of the substrate 10, respectively; and

providing a transparent layer 22, which is coated with an adhesive layer 23, on the frame layer 12, for covering the photosensitive chip 14.

The package processes for the image sensor is thus completed.

However, the image sensor has the following drawbacks.

1. The processes are complicated because the frame layer has to be arranged on the substrate 10, and the transparent layer 22 has to be coated with the adhesive layer 23 and then adhered onto the frame layer 12.

2. After the transparent layer 22 is placed on the frame layer 12 to cover the photosensitive chip, the plurality of wires 16 cannot be well protected. Thus, external impurities may tend to damage the plurality of wires 16, thereby influencing the signal transmission effects for the photosensitive chip 14 and lowering the overall yield.

3. Since the transparent layer has to cover the frame layer 12, the frame layer 12 may occupy some space above the substrate 10. Thus, the size of the packaged photosensitive chip 14 may be limited if the size of the substrate 10 is limited.

In view of the above-mentioned drawbacks, it is therefore an object of the invention to provide a photosensitive assembly with a transparent layer, which is capable of effectively solving the problems stated above, facilitating the manufacturing processes and lowering the manufacturing costs, and a method for manufacturing the same.

### SUMMARY OF THE INVENTION

An object of the invention is to provide a photosensitive assembly with a transparent layer, which is capable of simplifying and facilitating the manufacturing processes and lowering the manufacturing costs, and a method for manufacturing the same.

Another object of the invention is to provide a photosensitive assembly with a transparent layer, which is capable of protecting the wires, improving the signal transmission effects and increasing the production yield, and a method for manufacturing the same.

Still another object of the invention is to provide a photosensitive assembly with a transparent layer, which is capable of packaging a large-scale chip, and a method for manufacturing the same.

According to one aspect of the invention, a method for manufacturing photosensitive assemblies includes the steps of: providing a wafer having a plurality of photosensitive chips, each photosensitive chip having a photosensitive region and a plurality of bonding pads formed at a periphery of the photosensitive region; providing a plurality of transparent layers on the photosensitive regions of the photosensitive chips, respectively; and cutting the wafer into photosensitive assemblies using a cutter. Thus, each photosensitive chip may receive optical signals passing through the transparent layer.

According to another aspect of the invention, a photosensitive assembly includes a photosensitive chip, an adhesive layer arranged on the photosensitive chip, and a transparent layer. The photosensitive chip has a photosensitive region and a plurality of bonding pads formed at a periphery of the photosensitive region. The transparent layer is adhered to the photosensitive region of the photosensitive chip through the adhesive layer so that the photosensitive chip may receive optical signals passing through the transparent layer.

### BRIEF DESCRIPTION OF THE DRAWINGS

FIG. 1 is a schematic illustration showing a conventional image sensor structure.

FIG. 2 is a top view showing a wafer of the invention.

FIG. 3 is a top view showing the wafer having a transparent layer according to the embodiment of the invention.

FIG. 4 is a cross-sectional view showing a photosensitive assembly with a transparent layer according to the embodiment of the invention.

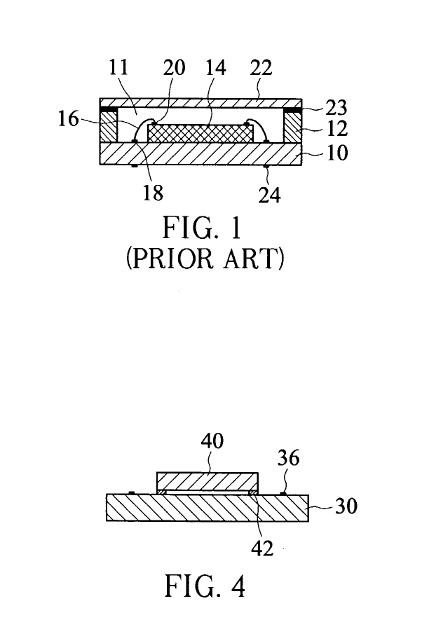

### DETAILED DESCRIPTION OF THE INVENTION

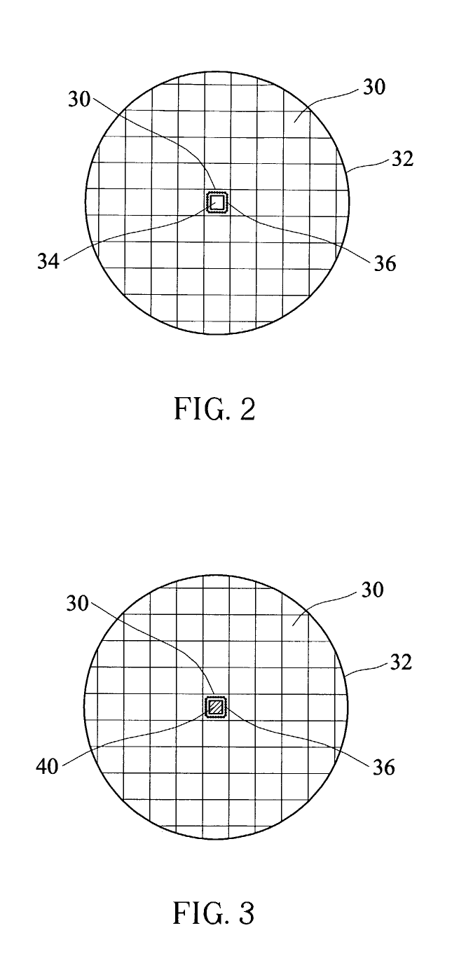

Please refer to FIG. 2, which is a top view showing a wafer of the invention. The method for manufacturing the photosensitive assembly of the invention will be described in the following. First, a wafer 32 having a plurality of photosensitive chips 30 is provided. Each photosensitive chip 30 has a photosensitive region 34 and a plurality of bonding pads 36 formed at a periphery of the photosensitive region 34.

Then, a plurality of transparent layers 40 having proper sizes is provided. In this embodiment, the transparent layers 40 are transparent glass layers. Next, as shown in FIG. 3, the transparent glass layers are cut and then adhered to the photosensitive regions 34 of the photosensitive chips 30 through the adhesive layers 42, respectively.

Finally, the wafer 32 is cut into a plurality of photosensitive assemblies using a cutter. At this time, each photosensitive assembly may have a transparent layer 40, as shown in FIG. 4. Thus, the photosensitive chip 30 may receive optical signals passing through the transparent layer 40. It is to be noted that the adhesive layers 42 are coated onto peripheries of the photosensitive regions 34, respectively.

According to the above-mentioned structure and method, the photosensitive assembly with the transparent layer and method for manufacturing the same have the following advantages.

1. Since the transparent layer 40 is first provided to cover and encapsulate the photosensitive region 34 of the photosensitive chip 30, it is possible to prevent the photosensitive region 34 of the photosensitive chip 30 of the image sensor from being contaminated during the wire bonding process, and the product yield may be improved.

2. Since the transparent layer 40 is first fixed to the photosensitive chips 30 on the wafer 32, which is then cut into photosensitive assemblies, the process for packaging the photosensitive assemblies may be simplified.

3. Since the transparent layer 40 has been provided on the photosensitive chip 30 of the invention, it is not necessary to conventionally provide a frame layer during package. Accordingly, the space for receiving the photosensitive chip above the substrate is enlarged, and the size of the photosensitive chip may also be enlarged.

While the invention has been described by way of examples and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

What is claimed is:

1. A photosensitive assembly, comprising:
a photosensitive chip having a photosensitive region and a plurality of bonding pads formed at a periphery of the photosensitive region;
an adhesive layer arranged on the photosensitive chip; and
a transparent glass layer adhered to the photosensitive region of the photosensitive chip through the adhesive layer so that the photosensitive chip may receive optical signals passing through the transparent glass layer.

2. The photosensitive assembly according to claim 1, wherein the adhesive layer is arranged on the periphery of the photosensitive region of the photosensitive chip.

3. A method for manufacturing a photosensitive assembly with a transparent layer, comprising:
providing a wafer having a plurality of photosensitive chips, each of the photosensitive chips having a photosensitive region and a plurality of bonding pads formed at a periphery of the photosensitive region;
adhering a plurality of transparent glass layers onto the photosensitive regions of the photosensitive chips through adhesive layers, respectively; and
cutting the wafer into a plurality of photosensitive chips using a cutter.

4. The method according to claim 3, wherein the adhesive layers are arranged at the periphery of the photosensitive regions of the photosensitive chips.
